(19) United States
(12) Patent Application Publication
(10) Pub. No.: US 2023/0387070 A1
(43) Pub. Date: Nov. 30, 2023

(54) BASIC MOLECULE-ASSISTED DIRECT BONDING METHOD

(71) Applicant: COMMISSARIAT À L'ENERGIE ATOMIQUE ET AUX ENERGIES ALTERNATIVES, Paris (FR)

(72) Inventors: Frank FOURNEL, Grenoble (FR); Aziliz CALVEZ, Grenoble (FR); Vincent LARREY, Grenoble (FR); Christophe MORALES, Grenoble (FR)

(73) Assignee: COMMISSARIAT À L'ENERGIE ATOMIQUE ET AUX ENERGIES ALTERNATIVES, Paris (FR)

(21) Appl. No.: 18/198,390

(22) Filed: May 17, 2023

(30) Foreign Application Priority Data
May 25, 2022 (FR) 22/05052

(51) Int. Cl. H01L 23/00; H01L 25/065

(52) U.S. Cl. CPC H01L 24/80; H01L 25/0657; H01L 24/05; H01L 24/08; H01L 2225/06565; H01L 2224/05187; H01L 2224/08145; H01L 2224/80085; H01L 2224/80896; H01L 2224/80203; H01L 2924/10253

(57) ABSTRACT

A method for manufacturing a multilayer structure by direct bonding between a first substrate and a second substrate includes the steps of: a) providing a first substrate and a second substrate respectively including a first bonding surface and a second bonding surface, b) bringing the first bonding surface and the second bonding surface into contact so as to create a direct bonding interface between the first substrate and the second substrate, c) disposing at least the direct bonding interface in a basic environment, and d) applying a thermal treatment at a temperature of between 20° C. and 350° C. so as to obtain the multilayer structure.

The present invention relates to the field of direct bonding. It concerns in particular a method for manufacturing a multilayer structure by direct bonding.

The direct bonding is a technique now well known and used for industrial applications such as the manufacture of SOI by the company SOITEC or the company STMicroelectronics for the production of imagers for example. As understood in the present document, the direct bonding is a spontaneous bonding between two surfaces without adding material to the interface between the bonded surfaces, and in particular without a thick layer of liquid. It is nevertheless possible to have some monolayers of water adsorbed on the surfaces, which represents between 0.25 nm and 1.25 nm in thickness, so that these surfaces are macroscopically dry.

The direct bonding is conventionally carried out at ambient temperature and ambient pressure, but this is not an obligation.

An important characteristic of the direct bonding is its adhesion energy, that is to say the energy available to carry out the spontaneous bonding. This is the energy that allows the two surfaces to be deformed to bring them into contact at the atomic scale so that the Van der Waals forces may be implemented. This adhesion energy partly directs the duration of the propagation of the bonding wave, for example the bonding wave propagates in a conventional way in 9 seconds for the direct bonding of two 200 mm silicon substrates. For example, for two surfaces of silicon or hydrophilic silicon oxide, the adhesion energy typically ranges from 30 to 100 mJ/m².

Another important characteristic of the direct bonding is its adherence energy or otherwise called its bonding energy. This is the energy that must be used to separate the two bonded surfaces. In the context of the bonding of two silicon substrates covered with thermal oxide of around 145 nm, this adherence typically varies between 0.14 J/m² and 6 J/m².

To obtain a spontaneous bonding, the surfaces are generally cleaned of organic and particulate contamination which is very detrimental to the direct bonding. For example, the cleaning is carried out beforehand on the surfaces to be bonded with a Caro acid-based solution obtained with a mixture of 96% sulfuric acid and 30% hydrogen peroxide (3:1) at 180° C. and SC1 (mixture of 30% ammonia, 30% hydrogen peroxide and deionized water (1:1:5)) at 70° C. Alternatively, it is possible to use other highly oxidizing cleaning solutions such as, for example, aqueous solutions containing ozone or else with a treatment using exposure to UV light in the presence of gaseous ozone. The adherence energy of a SiO₂—SiO₂ bonding (two silicon substrates covered with approximately 145 nm of thermal oxide for example), in a clean room environment, with a chemical cleaning based on Caro and SC1 at 70° C., is approximately 140 mJ/m² just after the bonding, without thermal treatment. The bonding energy also evolves according to the thermal treatment that is applied after the bonding carried out at ambient temperature. The adherence energy increases as a function of the temperature of the thermal treatments. For example, the SiO₂—SiO₂ bonding energy increases slowly to reach, depending on the surface treatments, 3 J/m² at 500° C. and then stagnates up to 800° C.

To further increase the bonding energy, another solution consists in carrying out a plasma treatment prior to the contacting. With a nitrogen (N₂) plasma, for an oxide-oxide bonding, the bonding energy increases rapidly to around 5 J/m² for a treatment temperature of 300° C.

However, the use of a plasma may be incompatible with certain substrates and/or its use lengthens the times and/or costs of the methods, which makes them more difficult to industrialize. The plasma treatment also modifies the surface over a thickness of a few nanometers (between 1 and 10 nm). This modification may affect the future devices. For example, with a silicon plate, the plasma creates an oxide layer which is difficult to control in terms of thickness and quality. With a silicon oxide surface, certain plasmas such as the N₂ plasma create interfacial charge problems that can disrupt the electrical operation of the future devices.

It has also been shown in the patent FR1912269 that the exposure of the Si and/or SiO2 surfaces to a specific molecule comprising a hydrophilic functional group and a basic functional group, before bringing the two surfaces into contact during the direct bonding method, brought a significant increase in the adherence energy of the bonded assembly after a thermal treatment in the range 100-500° C. The exposure of the surface(s) before bonding may be done by liquid process or by gas process.

One of the aims of the present invention is to propose a direct bonding method that is simple to implement and makes it possible to overcome the aforementioned drawbacks. To this end, the present invention proposes a method for manufacturing a multilayer structure by direct bonding between a first substrate and a second substrate, the method comprising the steps of:
a) providing a first substrate and a second substrate respectively comprising a first bonding surface and a second bonding surface,
b) bringing the first bonding surface and the second bonding surface into contact so as to create a direct bonding interface between the first substrate and the second substrate,
c) disposing at least the direct binding interface in a basic environment, and
d) applying a thermal treatment at a temperature of between 20° C. and 1000° C., in particular between 100° C. and 500° C., for example between 150 and 250° C., so as to obtain the multilayer structure.

This direct bonding method thus carried out makes it possible to obtain a multilayer structure having a bonding energy greater than that of a multilayer structure obtained by a direct bonding method devoid of step c) of treatment in a basic environment. A high bonding energy is then obtained at low temperature, that is to say at temperatures lower than 1000° C., preferably lower than or equal to 500° C. and even more preferably at a temperature of 200° C.

These bonding temperatures are compatible with numerous applications and/or with numerous substrates, the nature and/or the presence of electronic and/or opto-electronic components of which require low thermal budgets. In addition, the method is applicable to numerous materials and is inexpensive. The method leads to multilayer structures having good mechanical strength after bonding, compatible with subsequent methods such as Smart Cut™ and/or any method generating mechanical stresses on the assembly, such as for example mechanical thinning. Moreover, this method does not affect the adhesion energy since the use of a basic environment is only carried out after the direct contact between the surfaces. For example, the bonding wave always propagates in 9 seconds for silicon substrates of approximately 200 mm.

The post-bonding thermal treatment is also known to those skilled in the art as ‘bonding annealing’.

According to one possibility, the thermal treatment according to step d) is carried out by a rise in temperature, from ambient temperature to a final temperature, the rise in temperature being carried out with a slope of 0.1 to 10° C./min per example and more specifically from 0.5 to 5° C./min to then reach a stage lasting a few hours, for example 2 hours, at a final temperature between 200 and 300° C.

According to one possibility, step c) of disposing the direct bonding interface in a basic environment is carried out for a duration of approximately 1 hour to 80 days. The duration of this step increases with the diameter of the first and second substrates. It is indeed necessary that the basic molecules of the environment of step c) have time to move over the entire direct bonding interface to obtain a homogeneous and uniform bonding energy. Also, the greater the diameter of the multilayer structure, the greater the duration of step c).

According to one arrangement, the first bonding surface and/or the second bonding surface are/is formed at least in part by a hydrophilic film made of a material chosen from a native oxide, a thermal or deposited silicon oxide, a silicon nitride, a copper oxide and a combination of these materials.

Typically, the copper oxide hydrophilic film is a hybrid film composed of copper pads separated by SiO2. The copper pads are covered almost instantly in the air with a native copper oxide.

When the hydrophilic film is made of oxide, it is for example formed by a deposited oxide, a thin oxide film obtained by a thermal treatment (also called thermal oxide) and/or a thin oxide film obtained by a chemical treatment (also called native oxide or chemical oxide).

According to one variant, the first and/or second substrates are/is made of oxidized material(s), such as alumina, so that the first bonding surface and/or the second bonding surface are/is formed by the material respectively of the first and/or second substrate because it is an intrinsically hydrophilic material. This does not preclude the presence of an additional hydrophilic film.

According to a particular example, the first bonding surface is hydrophobic (for example made of hydrophobic silicon obtained by passivation of the silicon surface and hydrogen grafting onto the silicon) and the second bonding surface is hydrophilic. The second bonding surface is formed at least in part by a hydrophilic film chosen from a native oxide (of silicon, AsGa, InP, etc. depending on the material of the second substrate), a thermal oxide (of silicon), a deposited oxide, a silicon nitride, a copper oxide and a combination of these compounds, or else the second bonding surface consists of the material of the second substrate which is an oxide and therefore hydrophilic. Bringing the second hydrophilic surface into contact with the hydrophobic surface changes the initial hydrophobic character of the latter into a hydrophilic character, which allows the direct bonding.

Concretely, the first bonding surface and the second bonding surface are totally flat. In other words, the first and second bonding surfaces are devoid of recess or patterns forming plates at the microscopic scale.

The first bonding surface and/or the second bonding surface have/has a roughness of the order of one angstrom RMS, typically less than 5 angstrom RMS.

The first bonding surface and/or the second bonding surface have/has a peak-valley roughness of less than 5 nm.

According to one possibility, the first substrate and the second substrate have a diameter strictly greater than 2.5 cm.

Advantageously, step a) further comprises drying the first bonding surface and the second bonding surface before carrying out the contacting step b). After drying, the first bonding surface and the second bonding surface each have a face on which there resides at most one to five monatomic layers of H₂O, such that the first bonding surface and the second bonding surface are dry at the macroscopic scale.

Concretely, the basic environment is an aqueous basic solution. Also step c) consists in immersing at least the direct bonding interface in said aqueous basic solution. In other words, the multilayer assembly obtained in step b) is totally or partially immersed in the aqueous basic solution insofar as the direct bonding interface is immersed in said basic solution.

According to one arrangement, the aqueous basic solution has a pH strictly greater than 7.5, in particular greater than 8 and for example greater than 9.

According to one possibility, the aqueous basic solution is formed, by dissolving in deionized water, a basic compound chosen from NaOH, KOH, Na₂CO₃, NH₄OH, an amino alcohol and a mixture of these compounds; the amino alcohol being in particular selected from dimethylaminoethanol (or DMAE, CAS: 108-01-0), N,N-Diethyl-2-amino-ethanol (or DEAE, CAS: 100-37-8), monoethanolamine (CAS: 141-43-5), N-methyldiethanolamine (or MDEA, CAS: 105-59-9), am inomethanol (CAS: 3088-27-5), N-methylhydroxylamine (CAS: 593-77-1), diethanolamine (or DEA, CAS: 111-42-2), dimethanolamine (CAS: 7487-32-3), triethanolamine (CAS: 102-71-6), trimethanolamine (CAS: 14002-32-5) and a mixture of these amino alcohols.

According to one characteristic, the aqueous basic solution has a molar concentration of between 10⁻⁷ mol/l and 5 mol/l, for example between 10⁻⁶ mol/l and 1 mol/l and in particular between 0.01 mol/l and 0.5 mol/l of basic compound. A small amount of base is sufficient to ensure a strong bonding, which allows for an inexpensive step. Of course, a higher molar concentration is possible but without improving the obtained results.

According to one alternative embodiment, the basic environment is an atmosphere saturated with basic molecules in the vapor phase by evaporation in a hermetic enclosure of a basic stock solution comprising deionized water and a basic compound chosen from N,N-diethylethanolamine, N,N-dimethylethanolamine, 2-aminoethanol, N-methyldiethanolamine, aminomethanol, N-methylhydroxylamine, diethanolamine, dimethanolamine, triethanolamine, trimethanolamine, ethalonamine, diethyl-N—N-ethanol, ammonia and a mixture of these compounds.

According to one possibility, the basic stock solution includes a molar concentration of between 10⁻⁷ mol/l and 5 mol/l of an amino alcohol dissolved in deionized water. The basic stock solution is placed in a hermetic enclosure for one hour so as to obtain a gaseous environment saturated with gaseous amino alcohol. The multilayer assembly obtained in step b) is then disposed in the hermetic enclosure to subject the direct bonding interface to the atmosphere saturated with basic molecules in the vapor phase.

According to one arrangement, the temperature of the thermal treatment applied in step d) is between 20° C. and 1000° C., in particular between 100° C. and 500° C., in particular between 150° C. and 250° C.

According to one possibility, the first substrate and the second substrate are each formed by a material independently chosen from semiconductors, such as Si, Ge, InP, AsGa, SiC, GaN; LNO (acronym for lanthanum nickel oxide LaNiO3), LTO (acronym for lithium titanate Li2TiO3) and their combination.

The first and second substrates may be of identical nature or of different nature.

According to one particular embodiment, the first substrate and the second substrate provided in step a) each comprise a silicon substrate having a diameter of between 25 mm and 300 mm, for example between 100 and 300 mm and in particular 200 mm or 300 mm, and the first bonding surface and the second bonding surface are each formed by a silicon oxide film, step c) comprises disposing the direct bonding interface, obtained in step b), in the basic environment over a duration of between 21 and 40 days, in particular 30 days, the basic environment being an aqueous basic solution, formed by dissolution of NaOH and having a molar concentration of between 10⁻⁷ mol/l and 0.01 mol/l and in particular a molar concentration of approximately 10⁻³ mol/l, and step d) comprises applying a thermal treatment at approximately 300° C., so as to obtain a direct bonding between the first substrate and the second substrate having a bonding energy greater than 5 J/m².

The bonding energy is measured for example with the double lever method with imposed displacement in an anhydrous atmosphere as described in the article by F. Fournel, L. Continni, C. Morales, J. Da Fonseca, H. Moriceau, F. Rieutord, A. Barthelemy, and I. Radu, Journal of Applied Physics 111, 104907 (2012).

According to one variant embodiment, the first substrate provided in step a) comprises one or several first vignettes originating from the vignetting of the first substrate so as to obtain a direct bonding of the one or several first vignettes to the second substrate.

The first bonding surface is bounded by the exposed face of the one or several first vignettes.

According to another variant, the second substrate provided in step a) comprises one or several second vignettes originating from the vignetting of the second substrate so as to obtain a direct bonding between the one or several first vignettes and the one or several second vignettes.

The second bonding surface is bounded by the exposed side of the one or several second vignettes.

According to other characteristics, the method for manufacturing the multilayer structure of the invention includes one or several of the following optional characteristics considered alone or in combination:
The first substrate and/or the second substrate have/has a thickness greater than 50 micrometers, preferably greater than 100 micrometers, and for example a thickness of approximately 725 micrometers. The first substrate and/or the second substrate may be sufficiently thick layers to be self-supporting.
The first substrate and the second substrate are stacks of at least two layers of material of different nature.
The first bonding surface and the second bonding surface respectively of the first and second substrates are each formed at least in part by a hydrophilic film made of a native oxide, a silicon oxide, a silicon nitride, a copper oxide or a combination of these materials.
The first bonding surface and/or the second bonding surface respectively of the first and second substrates are each completely formed by a continuous hydrophilic film made of a native oxide, a silicon oxide, a silicon nitride or a copper oxide.
Only the first bonding surface or the second bonding surface has a hydrophilic character before the contacting.
The first substrate and/or the second substrate comprise(s) recesses emerging respectively at the first and/or second bonding surface(s).
The first bonding surface and the second bonding surface are devoid of any material added before the contacting in step b).
The method comprises before step b) of bringing the bonding surfaces into contact, a step consisting in applying a plasma treatment to the bonding surfaces of the first and second substrates. It is thus possible to substantially reduce the temperature of the thermal budget while conserving a high bonding energy.
The drying of the first bonding surface and of the second bonding surface comprises a centrifugation of the first and second substrates, in particular at 2000 revolutions/min for 45 s.
The drying of the first bonding surface and the second bonding surface includes a drying using the Marangoni effect.
The first bonding surface and/or the second bonding surface are/is cleaned with ozonated water before step b).
The first bonding surface and/or the second bonding surface are/is cleaned with a treatment SC1 and/or a treatment SC2 before step b).
The contacting according to step b) is preferably carried out at ambient temperature under an atmosphere having a relative humidity of approximately 75% or a lower humidity value or under vacuum (<5.10⁻² mbar) or under an anhydrous atmosphere (<0.5 ppm).
The first substrate and the second substrate provided in step a) each comprise a silicon substrate having a diameter of between 50 mm and 300 mm, for example between 100 mm and 200 mm, and the first bonding surface and the second bonding surface are each formed by a silicon oxide film, step c) comprises disposing the direct bonding interface, obtained in step b), in the basic environment over a duration of between 1 and 40 days, in particular the basic environment is an aqueous basic solution of NaOH having a molar concentration of between 10⁻⁷ mol/l and 5 mol/l in particular between 10⁻⁷ mol/l and 10⁻² mol/l and for example 10⁻³ mol/I, and step d) comprises applying a thermal treatment at 300° C., so as to obtain a direct bonding between the first substrate and the second substrate, the direct bonding having a bonding energy greater than 5 J/m².
The first and second substrates have a diameter of 50 mm and the duration of step c) is between approximately 1 and 2 days.
The first and second substrates have a diameter of 100 mm and the duration of step c) is between approximately 4 to 6 days.
The first and second substrates have a diameter of 200 mm and the duration of step c) is between approximately 15 and 20 days.
Step c) of disposing at least the direct bonding interface is carried out in a basic environment having a temperature of between the ambient temperature and 100° C. at the atmospheric pressure and for example between approximately 50° C. and 60° C.
The first and second substrates have a diameter of 300 mm and the duration of step c) is between approximately 35 to 40 days.
Step d) of applying the thermal treatment is carried out concomitantly with step c).
Step d) of applying the thermal treatment is carried out during step c) over a duration shorter than that of step c).

Other aspects, objects and advantages of the present invention will appear better upon reading the following description of various variant embodiments thereof, given by way of non-limiting example and made with reference to the appended drawings. In the remainder of the description, for the sake of simplification, identical, similar or equivalent elements of the different embodiments bear the same reference numerals. The figures do not necessarily respect the scale of all the elements represented so as to improve their readability and in which:

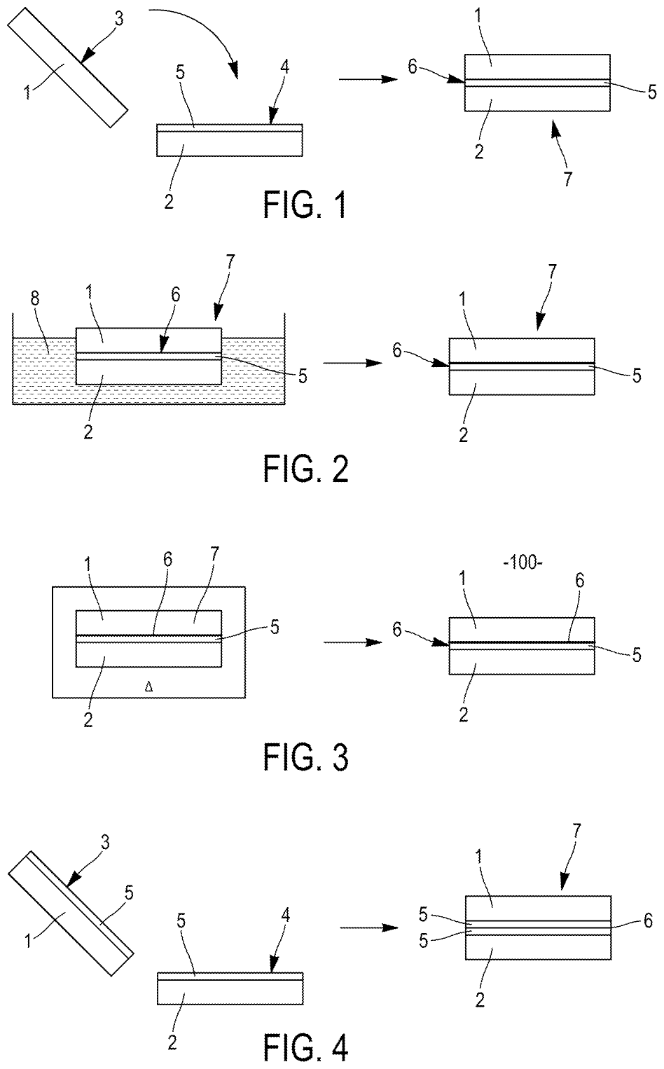

FIG. 1 represents a schematic view of steps a) and b) of the method according to a first embodiment of the invention.

FIG. 2 represents a schematic view of step c) of the method according to the first embodiment of the invention.

FIG. 3 represents a schematic view of step d) of the method according to the first embodiment of the invention.

FIG. 4 represents a schematic view of steps a) and b) of the method according to a second embodiment of the invention.

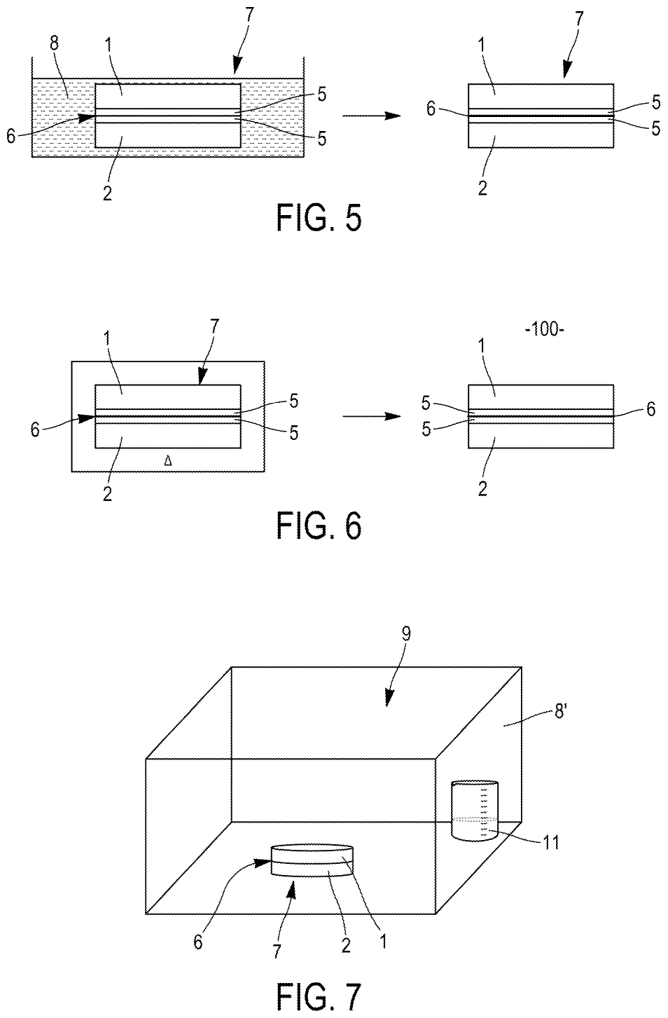

FIG. 5 represents a schematic view of step c) of the method according to the second embodiment of the invention.

FIG. 6 represents a schematic view of step d) of the method according to the second embodiment of the invention.

FIG. 7 represents a schematic view of step c) of the method according to one variant embodiment of the invention.

As illustrated in FIGS. 1 to 3, the direct bonding method of the present invention comprises the steps of bringing a first substrate 1 and a second substrate 2 into contact (FIG. 1 steps a and b), a step of disposing in a basic environment, namely a basic aqueous solution 8 whose pH is strictly greater than 7.5 (FIG. 2 step c) and a bonding annealing thermal treatment step so as to obtain a multilayer structure 100 having a bonding energy greater than that obtained without step c) of disposing in a basic environment (FIG. 3 step d). The first and second substrates 1,2 are made of silicon and have a diameter of 200 mm and a thickness of 725 micrometers. These two substrates 1,2 respectively comprise a first bonding surface 3 made of a native oxide of silicon (not visible in the figures) and a second bonding surface 4 made of thermal oxide of silicon (hydrophilic film 5 of oxide of 145 nm thick). The first and second surfaces 3,4 are prepared before the contacting by a cleaning with ozonated water, SC1 (mixture of 30% ammonia, 30% hydrogen peroxide and deionized water in the respective volume proportions 1:1:5) followed by SC2 (mixture of 30% hydrochloric acid, 30% hydrogen peroxide and water in the respective volume proportions 1:1:5). These cleanings make it possible to remove the organic and particulate contamination which is very detrimental to the direct bonding. According to a variant not illustrated, the step of preparing the surfaces before the contacting comprises a conventional plasma treatment.

The first and second bonding surfaces 3, 4 are then brought into contact for a spontaneous direct bonding (step b). The direct bonding interface 6 of the multilayer assembly 7 thus obtained is disposed in a basic environment consisting of a basic aqueous solution 8 of NaOH in deionized water with a molar concentration of approximately 10⁻³ mol/l (step c).

The immersion of the multilayer assembly 7 in the basic aqueous solution 8 is maintained for 30 days at the end of which the multilayer assembly 7 is subjected to a bonding annealing thermal treatment at 300° C. (step d—the rise in temperature from the ambient temperature at 1° C./min to 300° C. for 2 hours). The measurement of the energy of bonding to the multilayer structure 100 obtained leads to the breakage of the silicon substrates 1,2 and not to the detachment of the substrates 1,2. This indicates that the obtained bonding energy is greater than 5 J/m2 which is the rupture energy of silicon. The same method carried out without step c) of immersion in a basic environment leads to a bonding energy of 4 J/m2 after annealing at 500° C.

According to an alternative not illustrated, one of the two substrates 1,2 provided in step a) has an embrittlement plane. The bonding annealing thermal treatment contributes to the thermal budget allowing a fracture at the embrittlement plane. The obtained multilayer structure 100 then comprises one of the two substrates 1,2 bonded to a transferred thin layer originating from the fracture and a negative of the other of the substrates 1,2.

According to a variant not illustrated, the immersion time of the direct bonding interface 6 in the basic environment is approximately 5 hours for 25 mm/l substrates (15 days for 200 mm diameter substrates). The duration of the immersion is also variable according to the nature of the substrates 1,2.

As illustrated in FIG. 4, a silicon oxide film 5 may also form the bonding surfaces 3,4 of the first and second substrates 1,2. FIG. 4 illustrates the two bonding surfaces 3,4 brought into contact so as to form the direct bonding interface 6. FIG. 5 illustrates step c) of the method which consists in disposing the multilayer assembly 7 obtained at the step b) in a basic environment formed by an aqueous basic solution 8 comprising the amino alcohol DMAE (acronym for 2-(dimethylamino)ethanol) having a molar concentration of 10⁻² mol/I. The basic environment 8 covers the level of the direct bonding interface 6 and the immersion is maintained for 20 days. Then, the bonding reinforcement thermal treatment is applied at 200° C. to the multilayer assembly 7 for 3 hours according to step d) of the method.

These operations make it possible to obtain a reinforced bonding energy, in particular of more than 5 J/m2 at any point of the direct bonding interface 6 (value obtained by observing the rupture of the silicon during the application of the double lever method). When the same direct bonding method is carried out without step c), it is possible to separate the first and second substrates when applying the double lever method.

According to a variant embodiment illustrated in FIG. 7, the assembly 7 obtained in step b) is disposed in a basic environment formed by an atmosphere saturated with basic molecules in the vapor phase 8′. To this end, the method provides for the preparation of a hermetic enclosure 9 saturated with basic molecules in the vapor phase by evaporation of a basic stock solution 11 of ethalonamine having a concentration of 10⁻⁴ mol/l for one hour. Then the assembly is placed in the enclosure 9 for twice as long as with immersion (step c). After immersion of the direct bonding interface 6 in this atmosphere saturated with basic molecules in the vapor phase 8′, the assembly 7 is subjected to a thermal treatment at 300° C. for 2 hours (step d) to reinforce the bonding energy. At the end, the bonding energy measured by the double lever method is greater than 5 J/m².

According to another possibility not illustrated, the two bonding surfaces 3,4 are plasma treated before the contacting according to step b) of the method and the thermal annealing according to step d) is applied at a temperature of between approximately 20 and 250° C., for example at 50° C., for a few hours.

According to a variant not illustrated in the figures, the first and/or second substrates 1 and 2 are/is made of a material chosen from Ge, InP, AsGa, SiC, GaN, which have a bonding surface made of a hydrophilic film such as a native oxide of the considered material, LNO and LTO which intrinsically have a hydrophilic bonding surface.

According to yet another variant not illustrated, the first substrate 1 provided in step a) is vignetted in several first vignettes, the exposed faces of which are first bonding surfaces 3. The first vignettes are bonded according to the method previously described on the second substrate 2 (full plate) according to a chip-plate bonding also known by the expression ‘chip to wafer’. According to yet another variant not illustrated, the second substrate 2 is also vignetted in several second vignettes and the method of the invention allows the direct bonding of the first vignettes and the second vignettes.

According to an alternative not shown, the first bonding surface 3 and the second bonding surface 4 are prepared so as to have copper-oxide bondable hybrid surfaces in direct bonding. These first and second hydrophilic bonding surfaces 3,4 are typically composed of copper pads with sides of 2.5 micrometers separated by 2.5 micrometers of SiO₂. We then speak of a hybrid surface with a “pitch” of 5 micrometers. Then steps b) to d) of the method are reproduced as previously described.

Thus, the present invention proposes a method for manufacturing a multilayer structure 100 including a direct bonding between two substrates 1,2 having a high bonding energy, and making it possible to limit the temperature of the post-bonding thermal annealing. The preparation of a basic environment is inexpensive and the immersion step c) is applicable to many materials. It is in particular possible to bond substrates (or thick layers) of materials having a significant difference in thermal expansion coefficient. Moreover, when the materials of the first and second substrates 1,2 include devices, these are not damaged by the used temperatures.

It goes without saying that the invention is not limited to the variant embodiments described above by way of example but that it comprises all the technical equivalents and the variants of the means described as well as their combinations.

1. A method for manufacturing a multilayer structure by direct bonding between a first substrate and a second substrate, the method comprising the steps of:
a) providing a first substrate and a second substrate respectively comprising a first bonding surface and a second bonding surface,
b) bringing the first bonding surface and the second bonding surface into contact so as to create a direct bonding interface between the first substrate and the second substrate,
c) disposing at least the direct bonding interface in a basic environment, and
d) applying a thermal treatment at a temperature of between 20° C. and 1000° C. so as to obtain the multilayer structure.

2. The manufacturing method according to claim 1, wherein step c) of disposing the direct bonding interface in the basic environment is carried out for a duration of approximately 1 hour to 80 days.

3. The manufacturing method according to claim 1, wherein the first bonding surface and/or the second bonding surface are/is formed at least in part by a hydrophilic film made of a material chosen from a native oxide, a thermal or deposited silicon oxide, a silicon nitride, a copper oxide and a combination of these materials.

4. The manufacturing method according to claim 1, wherein the first bonding surface and the second bonding surface are completely flat.

5. The manufacturing method according to claim 1, wherein the basic environment is an aqueous basic solution.

6. The manufacturing method according to claim 5, wherein the aqueous basic solution is formed, by dissolving in deionized water, a basic compound chosen from NaOH, KOH, Na₂CO₃, NH₄OH, an amino alcohol and an mixture of these basic compounds; the amino alcohol being selected from 2-ethanol DMAE, N,N-diethyl-2-amino-ethanol, monoethanolamine, N-methyldiethanolamine, aminomethanol, N-methylhydroxylamine, diethanolamine, dimethanolamine, triethanolamine, trimethanolamine and a mixture of these amino alcohols.

7. The manufacturing method according to claim 5, wherein the aqueous basic solution has a molar concentration of between 10⁻⁷ mol/l and 5 mol/l of basic compound.

8. The manufacturing method according to claim 1, wherein the basic environment is an atmosphere saturated with basic molecules in the vapor phase, phase, by evaporation in a hermetic enclosure of a basic stock solution comprising deionized water and a basic compound chosen from N,N-diethylethanolamine, dimethylaminoethanol, aminoethanol, N-methyldiethanolamine, aminomethanol, N-methylhydroxylamine, diethanolamine, dimethanolamine, triethanolamine, trimethanolamine, ethalonamine, diethyl-N—N-ethanol, ammonia and their combination.

9. The manufacturing method according to claim 1, wherein the first substrate and the second substrate are each formed by a material chosen from semiconductors, LNO, LTO and their combination.

10. The manufacturing method according to claim 1, wherein:
the first substrate and the second substrate provided in step a) each comprise a silicon substrate having a diameter of between 25 mm and 300 mm, and in which the first bonding surface and the second bonding surface are each completely formed by a continuous hydrophilic film made of silicon oxide,
step c) comprises disposing the direct bonding interface, obtained in step b), in the basic environment over a duration of between 21 and 40 days, the basic environment being an aqueous basic solution formed by dissolution of NaOH and having a molar concentration of between 10⁻⁷ mol/l mol/l, and
step d) comprises applying a thermal treatment at approximately 300° C., so as to obtain a direct bonding between the first substrate and the second substrate having a bonding energy greater than 5 J/m².
